(19) United States
(12) Patent Application Publication
(10) Pub. No.: US 2014/0227878 A1
(43) Pub. Date: Aug. 14, 2014

(54) Method for Manufacturing Small-Size Fin-Shaped Structure

(71) Applicants: Tao Yang, Beijing (CN); Chao Zhao, Kessel-lo (BG); Junfeng Li, Beijing (CN); Yihong Lu, Beijing (CN)

(72) Inventors: Tao Yang, Beijing (CN); Chao Zhao, Kessel-lo (BG); Junfeng Li, Beijing (CN); Yihong Lu, Beijing (CN)

(73) Assignee: INSTITUTE OF MICROELECTRONICS, CHINESE ACADEMY OF SCIENCES, Beijing (CN)

(21) Appl. No.: 14/342,421

(22) PCT Filed: Mar. 5, 2012
(86) PCT No.: PCT/CN2012/072983

§ 371 Date: Mar. 3, 2014

(30) Foreign Application Priority Data
Sep. 5, 2011 (CN) 2011102611527.6

(51) Int. Cl. H01L 21/308

(52) U.S. Cl. CPC H01L 21/3086
USPC 438/702

(57) ABSTRACT

A method for manufacturing a small-size fin-shaped structure, comprising: forming a first mask layer and a second mask layer on a substrate in sequence; etching the first mask layer and the second mask layer to form a hard mask pattern, wherein a second mask layer pattern is wider than a first mask layer pattern; eliminating the second mask layer pattern; and performing a dry etching of the substrate by taking the first mask layer pattern as a mask, so as to form a fin-shaped structure. According to the method for manufacturing a small-size fin-shaped structure of the present invention, firstly a large-size hard mask is prepared, then a width controllable small-size hard mask is prepared through a wet corrosion, and finally the bulk silicon wafer is etched, so as to obtain the required small-size fin-shaped structure, thereby improving the electrical properties and the integration level of the device, simplifying the processes and reducing the cost.

This application claims priority to a Chinese Patent Application No. 201110261527.6, filed on Sep. 5, 2011, entitled “method for manufacturing small-size fin-shaped structure”, which is hereby incorporated by reference in its entirety.

### FIELD OF THE INVENTION

The present invention relates to a method for manufacturing a semiconductor device, and particularly, to a method for manufacturing a small-size fin-shaped structure.

### BACKGROUND OF THE INVENTION

With the continuous decrease of the semiconductor feature size towards the level of 22/15 nm, the negative effect caused by the grid width reduction becomes increasingly obvious, and the traditional planar transistor cannot meet the requirement. Firstly, in order to eliminate the short channel effect, P and B shall be heavily doped into the channel. As a result, the threshold voltage of the device rises, the carrier mobility in the channel is reduced, and the response speed of the device decreases. In addition, it is difficult to control the ion implantation process, and undesirable results are easily to be caused, e.g., the threshold voltage fluctuates too much. Secondly, the traditional SiGe PMOS strained silicon technology also faces a bottleneck: in the 22 nm process node, the content of Ge element doped at the source and drain electrodes has reached about 40%, and it is difficult to provide the channel with a higher level strain. Thirdly, a bottleneck also occurs during the development of the thickness of the gate oxide, and it has been difficult for the thickness thinning speed to keep up with the gate width narrowing speed.

In May 2011, Intel announced that the 22 nm technology node will use a device structure of 3D FinFET to replace the former planar device structure of 2D FET, so as to solve the problems such as electricity leakage and high power consumption caused by the reduction of the device size. Since the 2D planar FET always maintains the progress of Moore's Law before the 22 nm technology node, people are all concerned about whether it is necessary to introduce the 3D FinFET, and at which technology node the introduction shall be made. The prototype and the manufacturing process of the 3D FinFET have been studied for more than 10 years. The device structure of 3D FinFET is illustrated in FIG. 1 which is published by Intel, in which an oxide layer 2 is formed on a bulk silicon substrate 1; parallel fin-shaped or wing-shaped structures 3 are protruded from the substrate 1 and vertically arranged, and they are formed through a selective epitaxial growth, a substrate etching and an oxide filling or using the Silicon Nanowires technology; ultra-thin gate oxide layers 4 are formed on the fin-shaped structures 3 and they surround the channel regions; a gate 5 is formed on the oxide layer 2, while it covers the ultra-thin gate oxide layers 4, surrounds the channel regions and crosses the fin-shaped structures 3; impurities are doped into the fin-shaped structures 3 on both sides of the gate 5 to form a source/drain region 3A/3B, while some regions of the fin-shaped structures 3 covered by the gate 5 and the gate oxide layers 4 become a channel region 3C, wherein the source/drain region 3A/3B and the channel region 3C need to be thin enough to enhance the gate control capability.

One of the key technologies of the device structure is to form fin-shaped monocrystal grid bars on corresponding bulk silicon wafer substrate and take the grid bars as the source/drain region of the device. However, in the existing integrated circuit process, it is difficult to manufacture small-size fin-shaped structures on the bulk substrate through known conventional processes such as deposition and etching, while new technologies, such as silicon nanotube, are difficult to be used for mass production due to complex processes and high costs, and their process uniformities need to be improved.

In view of the above reasons, what is needed, therefore, is to provide a method for manufacturing a small-size fin-shaped structure with a high efficiency and a low cost.

### SUMMARY OF THE INVENTION

Thus, an object of the present invention is to provide a method for manufacturing a small-size fin-shaped structure, so as to manufacture the small-size fin-shaped structure with a high efficiency and a low cost, thereby improving the device performance while efficiently reducing the cost.

The present invention provides a method for manufacturing a small-size fin-shaped structure. The method comprises: forming a first mask layer and a second mask layer on a substrate in sequence; etching the first mask layer and the second mask layer to form a hard mask pattern, wherein a second mask layer pattern is wider than a first mask layer pattern; eliminating the second mask layer pattern; and performing a dry etching of the substrate by taking the first mask layer pattern as a mask, so as to form a fin-shaped structure.

In which, a dry etching is firstly performed to form a hard mask pattern, with a width of the second mask layer pattern being the same as that of the first mask layer pattern, then a wet corrosion of the first mask layer pattern is carried out so that the second mask layer pattern is wider than the first mask layer pattern.

In which, the first mask layer and/or the second mask layer comprise(s) silicon oxide, silicon nitride or silicon oxynitride.

The corrosion liquid for the wet corrosion comprises diluted hydrofluoric acid (DHF), BOE, hot phosphoric acid or H₂O₂.

The substrate comprises monocrystal silicon, Silicon-On-Insulator (SOI), monocrystal germanium, Germanium-On-Insulator (GeOI), SiGe, SiC, InSb, GaAs or GaN.

In which, the crystal orientation of the substrate depends on the carrier mobility control.

In which, the first mask layer pattern and/or the fin-shaped structure have/has a width less than or equal to 100 Å.

According to the method for manufacturing a small-size fin-shaped structure of the present invention, firstly a large-size hard mask is prepared, then a width controllable small-size hard mask is prepared through a wet corrosion, and finally the bulk silicon wafer is etched, so as to obtain the required small-size fin-shaped structure, thereby improving the electrical properties and the integration level of the device, simplifying the processes and reducing the cost.

The object of the present invention and other objects not listed herein are satisfied in the scope of the independent claims of the present application. The embodiments of the present invention are defined by the independent claims, and the specific features are defined by the dependent claims.

### BRIEF DESCRIPTION OF THE DRAWINGS

The technical solutions of the present invention are described in detail as follows with reference to the drawings, in which:

FIG. 1 illustrates a schematic diagram of a fin-shaped gate device in the prior art; and

FIGS. 2 to 7 illustrate cross-section diagrams in respective steps of a method according to the present invention in sequence.

### DETAILED DESCRIPTION OF THE EMBODIMENTS

The features and technical effects of the technical solutions of the present invention are described in detail as follows with reference to the drawings and in conjunction with the exemplary embodiments, in which a method for manufacturing a small-size fin-shaped structure is disclosed. To be noted, similar reference signs denote similar structures.

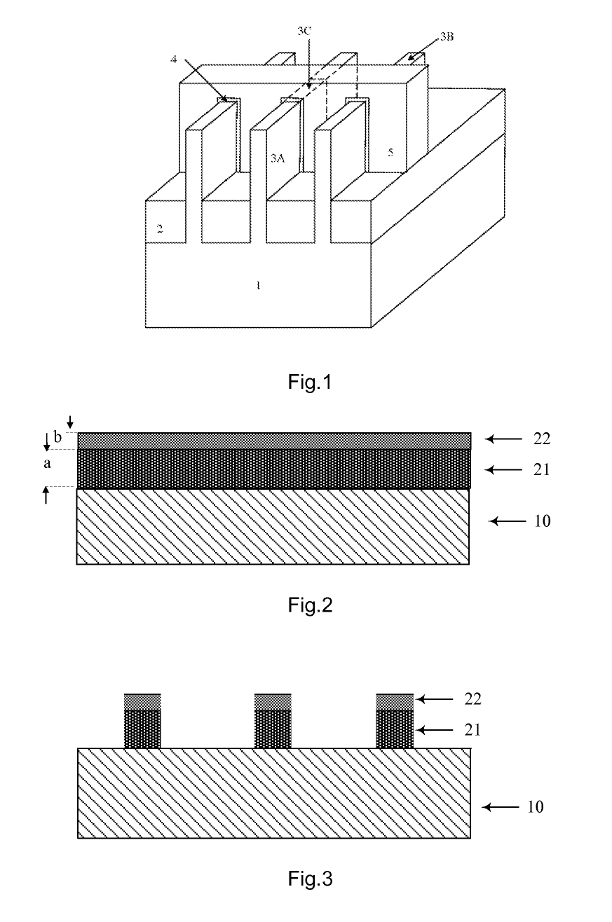

Firstly referring to FIG. 2, a hard mask material layer 20 consisting of a first mask layer 21 and a second mask layer 22 is formed on a substrate 10 for example in a conventional deposition method such as LPCVD and PECVD. The substrate 10 may use various substrate materials based on the requirement of the device electrical properties. For example, the substrate 10 includes monocrystal silicon, Silicon-On-Insulator (SOI), monocrystal germanium, Germanium-On-Insulator (GeOI) or other compound semiconductor materials such as SiGe, SiC, InSb, GaAs and GaN, or it may be an epitaxial wafer. The crystal orientation of the substrate 10 may be (100), (110) or (111) depending on the requirement of the carrier mobility control. Alternatively, a plurality of top substrate regions having different crystal orientations may be formed through a Selective Epitaxial Growth (SEG) on the bottom substrate. The first mask layer 21 and the second mask layer 22 may comprise silicon oxide, silicon nitride or silicon oxynitride. The materials of the two mask layers used for the hard mask layer to be etched later are different from each other, for example the silicon nitride 22 is located on the silicon oxide 21, or the silicon oxide 21 is located on the silicon nitride 22. Alternatively, a three-layer structure may be employed so that the rates of the later etchings are different from each other, and particularly, the etching of the lower layer is faster than that of the intermediate layer, while the etching of the intermediate layer is faster than that of the upper layer. The first mask layer 21 has a thickness a of about 400˜1000 Å, and preferably 600 Å. The second mask layer 22 has a thickness b of about 100˜400 Å, and preferably 200 Å.

Next, referring to FIG. 3, vertical hard mask patterns with equal widths up and down are formed by etching. Photoresist (not shown) is coated on the second mask layer 22, then exposed and developed to form a photoresist pattern. The photoresist pattern is taken as a mask and a dry etching such as plasma etching is employed to etch the second mask layer 22 and the first mask layer 21 in sequence, until the substrate 10 is exposed, so as to form a hard mask pattern having a line width such as about 200˜400 Å and preferably 300 Å. In which, the plasma etching gases may comprise halogen-containing gases, such as, fluorine-containing gases such as fluorocarbon-based gases (CxHyFz), NF3, SF6, etc., or other halogen-containing gases such as Cl₂, Br₂, HBr, HCl, etc. The plasma etching gases may further comprise oxidants such as oxygen, ozone or oxynitride. To be noted, the second mask layer 22 acting as the top layer is not completely eliminated during the plasma etching, and a certain thickness is reserved, for example larger than or equal to 100 Å and preferably 150 Å. When the etching is finished, the etching product is thoroughly eliminated through a wet cleaning using deionized water, etc., or a dry cleaning that feeds oxygen, fluorinated gases, etc.

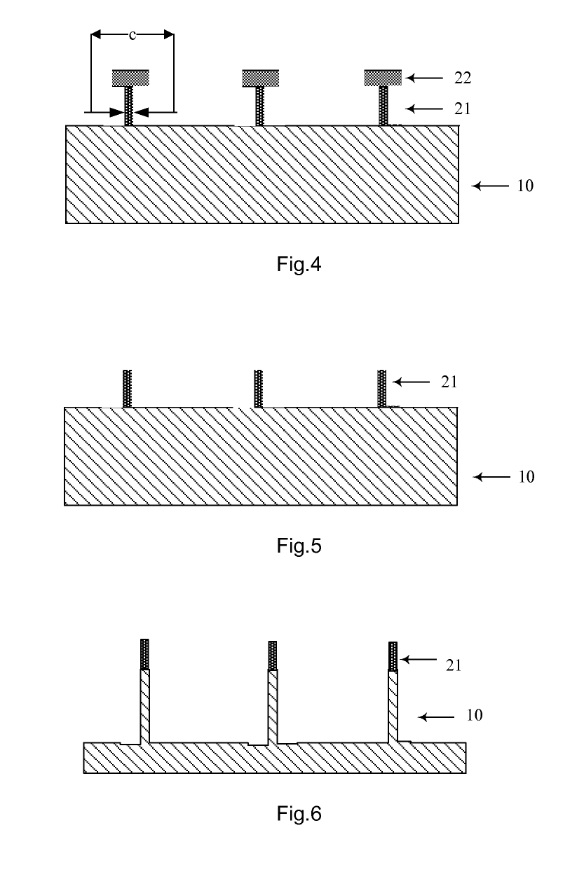

Next, referring to FIG. 4, hard mask patterns wider at the top and narrower at the bottom are formed through selective etchings. Different etching liquid is selected depending on the materials of the first and second mask layers, so as to selectively perform a wet etching of the first mask layer and form a hard mask pattern wider at the top and narrower at the bottom. In case the first mask layer 21 is made of silicon oxide, an HF-based chemical liquid such as diluted hydrofluoric acid (DHF, e.g., HF:H₂O=1:100) or buffer oxide etch (BOE, a mixture of NH4F and HF with the ratio from 2:1 to 4:1) is employed, and the etching temperature is for example 25° C. Since DHF corrodes the second mask layer 22 made of silicon nitride in a very slow rate while corrodes the first mask layer 21 made of silicon oxide in a relative fast rate, the lines of the first mask layer pattern 21 will be transversely retracted, thereby forming a structure wider at the top and narrower at the bottom, which is similar to a nut or T-shape, as illustrated in FIG. 4. In case the first mask layer 21 is made of silicon nitride, it may be laterally corroded using a hot phosphoric acid (H₃PO₄:H₂O=85:15, and the process temperature may be testified as 160° C.) that does not react with the second mask layer 22 made of silicon oxide, thereby also forming the structure as illustrated in FIG. 4. Similarly, in case the mask layer 21 or 22 is made of oxynitride, it may be corroded using a mixture of HF and H₂O₂. In FIG. 4, the line width of the second mask layer 22 is still close or equal to the pattern width of the hard mask as illustrated in FIG. 3, for example about 200˜400 Å and preferably 300 Å. But the line width c of the first mask layer pattern 21 is smaller than that of the second mask layer pattern 22, for example less than or equal to 100 Å and preferably 50 Å. In other words, the second mask layer 22 has suspended portions exceeding the first mask layer 21 for 125 Å leftwards and rightwards, respectively. The width of the suspended portion or the remained line width c of the first mask layer pattern 21 may be obtained by controlling the transverse corrosion rate by adjusting the ratio and the temperature of the corrosive liquid, so as to control the width of the fin-shaped structure finally formed by etching the substrate.

In case the SiO₂/Si₃N₄ (SiON) double-stacked hard mask structure is only made of one layer of SiO₂ hard mask, the top and sides of the single-layer SiO₂ hard mask will be corroded simultaneously during the transverse wet corrosion of SiO₂, because they are not protected by the top layer Si₃N₄ (SiON), and thus the shape and the transverse width of the SiO₂ hard mask cannot be effectively controlled. As such, the present invention controls the transverse width using a double-layer hard mask, thereby finally forming a small-size fin-shaped structure.

Next, referring to FIG. 5, the second mask layer on the top is eliminated. The second mask layer pattern 22 remained on the top of the hard mask pattern is eliminated using a wet corrosion process, and only the first mask layer pattern 21 is reserved on the substrate 10. For example, a hot phosphoric acid (H₃PO₄:H₂O=85:15, and the process temperature may be testified as 160° C.) may be used to corrode the second mask layer 22 of the silicon nitride. In case the second mask layer 22 is made of silicon oxide, it may be corroded and eliminated using an HF-based chemical liquid such as diluted hydrofluoric acid (DHF, e.g., HF:H₂O=1:100) or buffered oxide etch (BOE, a mixture of NH₄F and HF with the ratio from 2:1 to 4:1), and the etching temperature for example is 25° C. When the wet corrosion process is finished, the wafer is cleaned and dried.

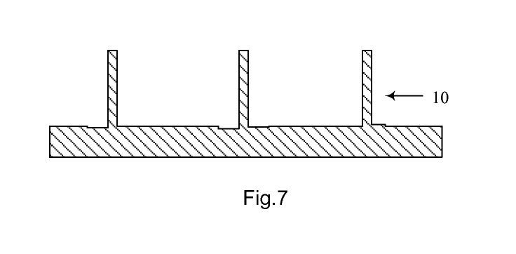

Next, referring to FIG. 6, the fin-shaped structures are formed by etching the substrate. A dry etching process, such as plasma etching, identical or similar to that used for etching the hard mask pattern is employed. The reserved first mask layer pattern 21 is taken as the mask to etch the substrate until a required depth is achieved, for example about 200˜1000 Å. The portions of the substrate 10 not sheltered by the first mask layer pattern 21 are etched and eliminated, while the portions of the substrate 10 under the first mask layer pattern 21 are reserved, thereby forming a plurality of fin-shaped structures as illustrated in FIG. 6. In which, the width of the fin-shaped structure is equal to the remained width c of the first mask layer pattern, for example less than or equal to 100 Å, and preferably 50 Å.

Finally referring to FIG. 7, the remained first mask layer pattern 21 is eliminated. Different wet etching liquid is adopted depending on the material of the first mask layer 21, so as to corrode and eliminate the remained first mask layer pattern 21 while reserving a plurality of fin-shaped structures as illustrated in FIG. 7. For example, in case the first mask layer 21 is made of silicon oxide, an HF-based etching liquid is employed. In case the first mask layer 21 is made of silicon nitride, hot phosphoric acid is employed. In case the first mask layer 21 is made of silicon oxynitride, a mixture of HF and hydrogen peroxide is employed.

The subsequent device manufacturing may comprise depositing a gate dielectric layer and a gate material layer on the fin-shaped structure, implanting ions to sources and drains of the fin-shaped structures on both sides of the gate, depositing and etching an insulation layer to form a contact hole, depositing contact metal, etc., thereby completing the manufacturing of the fin-shaped gate device. These processes are known in the art, and herein are omitted.

According to the method for manufacturing a small-size fin-shaped structure of the present invention, firstly a large-size hard mask is prepared, then a width controllable small-size hard mask is prepared through a wet corrosion, and finally the bulk silicon wafer is etched, so as to obtain the required small-size fin-shaped structure, thereby improving the electrical properties and the integration level of the device, simplifying the processes and reducing the cost.

Although the present invention has been described with reference to one or more exemplary embodiments, a person skilled in the art shall be appreciated that various suitable changes and equivalents can be made to the device structure without deviating from the scope of the present invention. In addition, many modifications suitable to particular situations or materials may be made under the disclosed teaching without deviating from the scope of the present invention. Therefore, the present invention is not limited to the specific embodiments disclosed as the most preferred embodiments for implementing the present invention, and the disclosed device structure and the method for manufacturing the same include all the embodiments falling within the scope of the present invention.

1. A method for manufacturing a small-size fin-shaped structure, comprising:
forming a first mask layer and a second mask layer on a substrate in sequence;
etching the first mask layer and the second mask layer to form a hard mask pattern, wherein a second mask layer pattern is wider than a first mask layer pattern;
eliminating the second mask layer pattern; and
performing a dry etching of the substrate by taking the first mask layer pattern as a mask, so as to form a fin-shaped structure.

2. The method according to claim 1, wherein a dry etching is firstly performed to form a hard mask pattern, with a width of the second mask layer pattern being the same as that of the first mask layer pattern, then a wet corrosion of the first mask layer pattern is carried out so that the second mask layer pattern is wider than the first mask layer pattern.

3. The method according to claim 1, wherein the first mask layer and/or the second mask layer comprise(s) silicon oxide, silicon nitride or silicon oxynitride.

4. The method according to claim 2, wherein the wet corrosion is carried out in the presence of a corrosion liquid comprising diluted hydrofluoric acid (DHF), buffered oxide etch (BOE), hot phosphoric acid or H₂O₂.

5. The method according to claim 1, wherein the substrate comprises monocrystal silicon, Silicon-On-Insulator (SOI), monocrystal germanium, Germanium-On-Insulator (GeOI), SiGe, SiC, InSb, GaAs or GaN.

6. The method according to claim 1, wherein the crystal orientation of the substrate depends on the carrier mobility control.

7. The method according to claim 1, wherein the first mask layer pattern and/or the fin-shaped structure have/has a width less than or equal to 100 Å.
